(19) United States
(12) Patent Application Publication
(10) Pub. No.: US 2011/0194252 A1
(43) Pub. Date: Aug. 11, 2011

(54) MOBILE ELECTRONIC DEVICES WITH INTEGRATED PERSONAL COOLING FAN

(75) Inventor: Eric Wang, Shanghai (CN)

(73) Assignee: NXP B.V., Eindhoven (NL)

(21) Appl. No.: 12/919,473

(22) PCT Filed: Feb. 27, 2009
(86) PCT No.: PCT/IB09/50811

§ 371 Date: Dec. 3, 2010

(30) Foreign Application Priority Data
Feb. 28, 2008 (US) 61031945

(51) Int. Cl. H05K 7/20

(52) U.S. Cl. 361/695

(57) ABSTRACT

A personal cooling fan is integrated into a mobile electronic device (110, 210, 310). The mobile electronic device (110, 210, 310) has a vibration alert system that includes control circuitry (140, 340) to control a vibration motor (120, 320), and the personal cooling fan system is also controlled by the control circuitry (140, 340). The personal cooling fan system includes a rotary motor (130, 320) contained within a housing (112, 212, 110 312) of the device, a drive shaft (150, 250, 350) having a first portion engaged by the rotary motor (130, 320) and having a second portion protruding from the housing (112, 212, 312), and fan blades (160, 260, 360) removably attached to the second portion of the drive shaft (150, 250, 350) such that the rotary motor (130, 320) is operable to rotate the drive shaft (150, 250, 350) thereby spinning the fan blades (160, 260, 360). The drive shaft (150, 250, 350) may be extended from the housing (112, 212, 312) to attach the fan blades (160, 260, 360) and operate the fan, and retracted into the housing (112, 212, 312) when the fan is not in use.

The present invention relates generally to mobile electronic devices having a vibration motor and control circuitry, and to such devices having an integrated personal cooling fan.

Mobile phones and PDAs have become ubiquitous in modern society. Along with the widespread daily use of such devices for communication, demand has grown for additional services and functionality. At the same time, consumers demand mobile devices that are smaller and more stylish, and that are easily stowed or concealed.

Various aspects of the present invention are directed to mobile electronic devices having vibration alert systems that include control circuitry to control a vibration motor, and a personal cooling fan system controlled by the control circuitry. The personal cooling fan system includes a rotary motor contained within a housing of the device, a drive shaft having a first portion engaged by the rotary motor and having a second portion protruding from the housing, and fan blades removably attached to the second portion of the drive shaft such that the rotary motor is operable to rotate the drive shaft thereby spinning the fan blades.

The above summary is not intended to describe each embodiment or every implementation of the present disclosure. The figures and detailed description that follow more particularly exemplify various embodiments.

The invention may be more completely understood in consideration of the following detailed description of various embodiments of the invention in connection with the accompanying drawings, in which:

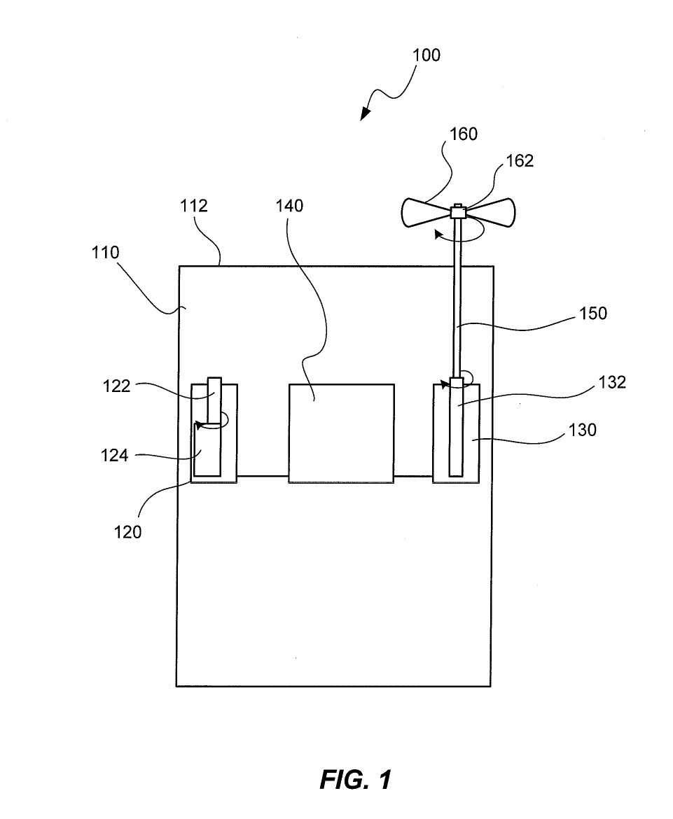

FIG. 1 schematically illustrates a mobile device incorporating a personal cooling fan in accordance with certain embodiments of the present invention;

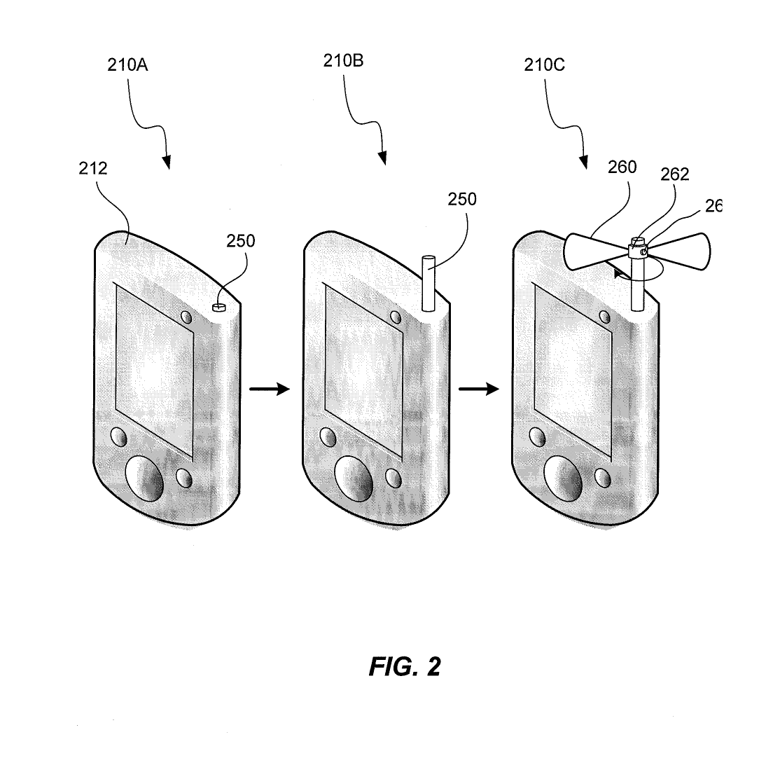

FIG. 2 schematically illustrates another mobile device incorporating a personal cooling fan in accordance with certain embodiments of the present invention; and

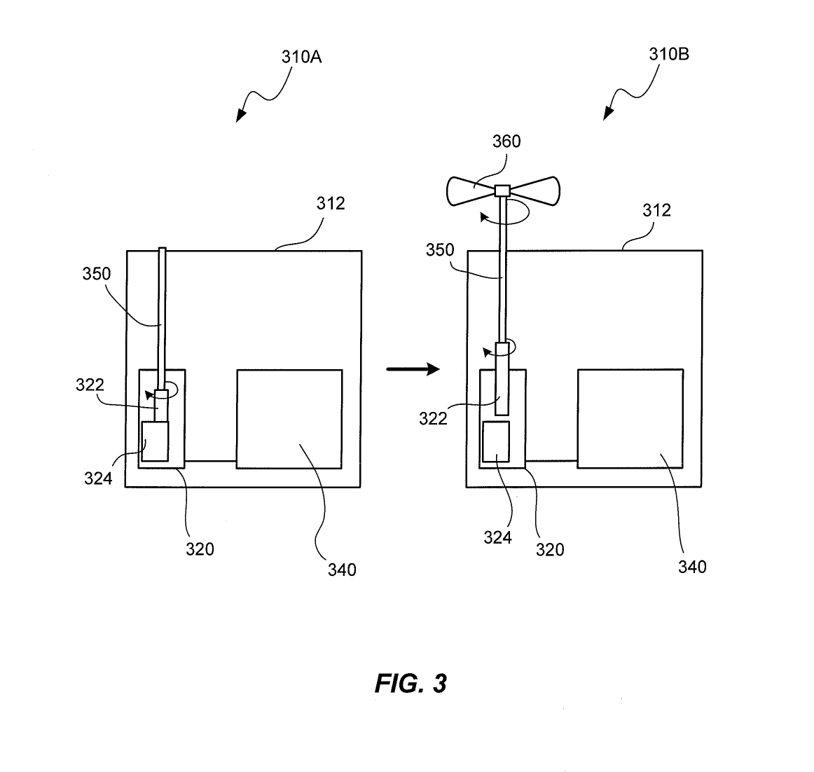

FIG. 3 schematically illustrates yet another mobile device incorporating a personal cooling fan in accordance with certain embodiments of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention including aspects defined by the appended claims.

Embodiments of the present invention relate to integrating a personal cooling fan function into mobile electronic devices such as cellular phones or PDAs, and in particular into mobile electronic devices that include a vibration alert system. Such mobile electronic devices are generally of the type that users habitually carry with them wherever they go, and as such the personal cooling fan function can be made readily available without the requirement of carrying a separate mini fan. In certain embodiments, the present invention adapts the control circuitry and/or rotary motors currently implemented only for providing a vibration alert signal, and uses such components to drive the rotary action of a personal cooling fan.

In certain embodiments, the present invention provides mobile electronic devices having a vibration alert system including control circuitry to control a vibration motor and a personal cooling fan system controlled by the control circuitry. The personal cooling fan system includes a rotary motor contained within a housing of the device, a drive shaft having a first portion engaged by the rotary motor and having a second portion protruding from the housing, and fan blades removably attached to the second portion of the drive shaft such that the rotary motor is operable to rotate the drive shaft thereby spinning the fan blades.

FIG. 1 illustrates a mobile electronic device 110 such as a cell phone, PDA, or other such portable device that includes a vibration motor 120 controlled by circuitry 140. Vibration motor 120 is a rotary motor that spins an off-center, or eccentric, weight 124 on an axis 122 to create a vibrating effect. The vibration can serve as haptic-based sensory alert used in addition to or instead of a more audio-intrusive ringer or other audible alarm. Mobile phones are commonly equipped with such vibration motors and control circuitry.

In accordance with certain embodiments, mobile electronic device 110 also includes a rotary motor 130 that drives the spinning action of an axis 132. Rotary motor is also connected to and controlled by circuitry 140. A drive shaft 150 is coupled to motor axis 132 so that the drive shaft is also rotated upon operation of the rotary motor 130. In an extended position, drive shaft 150 protrudes from the housing 112 of device 110 sufficiently far to allow secure installation of fan blades 160 in such a manner that the fan blades can be safely rotated to provide blowing action without the fan blade motion being impeded by the device housing 112.

Drive shaft 150 may be detachable from axis 132 so that it can be removed when the fan is not in use. Drive shaft 150 may additionally or alternatively be extendable from and retractable into the housing 112, for example by providing drive shaft 150 in two or more telescoping members. Drive shaft 150 may be manually extendable and/or its extension can be controlled by circuitry 140. For example, when a user selects the fan function from a user interface menu or by using a dedicated hardware button or switch, the circuitry may be used to automatically extend the drive shaft. The user may then be prompted to turn on the fan, select a fan speed, and so forth. The circuitry 140 may be the same circuitry used to drive vibration motors, and adapted to control the fan motor 130 using software or firmware uploaded to and stored in the device. For example, the rotary speeds used to drive the personal cooling fan are typically much higher than the speeds used to drive the vibration motor.

Fan blades 160 are detachable when the fan is not in use. When the fan blades 160 are detached, they may be compactly folded for easy carrying, for example in a pocket of a carrying case for the mobile device. The fan blades 162 may be rigidly or foldably connected to a drive hub 162 that attaches to the drive shaft 150, for example using a removable pin, a set screw, or the like. Alternatively, the fan blades may be individually mounted to the drive shaft.

Control circuitry 140 may be incorporated into the baseband chip of the mobile device 110. In controlling rotary motor 130, the control circuitry 140 may provide two signals to the motor 130, a first of which signals being in response to a user selecting to use the fan function, and a second of which signals powering the motor and controlling its speed. Existing circuitry can control the fan motor with the signals being enabled by software that also provides the user interface.

FIG. 2 illustrates the extension of a drive shaft and connection of fan blades in accordance with certain embodiments. Starting at the left hand side of FIG. 2, mobile device 210A includes a drive shaft 250 in a retracted position relative to housing 212. Extending the drive shaft 250 from the housing results in device 210B, which is ready for attaching the fan blades 260. As noted, extension of the drive shaft may be performed manually by the user, or controlled automatically by the fan control circuitry. Device 210C illustrates the fan blades 260 attached to a protruding part of the drive shaft sufficiently far from the housing to allow the fan blades to rotate unimpeded. Fan blades 260 are optionally attached to a rotary hub 262 that may be secured to the drive shaft using a set screw 264, or by other suitable means.

FIG. 3 schematically illustrates an embodiment where the vibration motor of a mobile device is used to power a personal cooling fan. A mobile device 310A includes a rotary motor 320 rotationally driving an axis 322 that is coupled to an eccentric weight 324. Control circuitry 340 controls the rotary motor to vibrate the device by spinning the eccentric weight. A drive shaft 350 is also coupled to the axis 322. When drive shaft 350 is in a retracted position relative to the device housing 312 as shown for device 310A, the axis 322 is coupled to eccentric weight 324, and the motor 320 provides vibration.

Mobile device 310B indicates the drive shaft 350 extended from housing 312, and fan blades 360 attached to a protruding part of the drive shaft. When the drive shaft 350 is extended, the motor axis 322 is decoupled from the eccentric weight 324 in such a manner that the motor 320 still rotatably drives the axis 322, but the axis 322 no longer spins the weight. As such, the drive shaft 350 spins without encumbrance from the eccentric weight or the resulting vibration. The spinning of drive shaft 350 rotates the fan blades 360 to provide blowing action for personal cooling. When the fan function is no longer desired, the fan blades 360 are detached and the drive shaft 350 is retracted, thus re-coupling the axis 322 to the eccentric weight 324. When the extension of the drive shaft is performed manually by the user, a sensor (not shown) may be used to detect whether the drive shaft is in an extended or retracted position, and provide a signal to the control circuitry 340 indicating whether vibration motor controls or fan motor controls should be used. For example, the fan function may provide a higher rotation speed than that used for the vibration function. In the case where the drive shaft is automatically extended, the user interface software may provide a signal to the control circuitry indicated that fan motor controls should be used.

While the present invention has been described above and in the claims that follow, those skilled in the art will recognize that many changes may be made thereto without departing from the spirit and scope of the present invention. For example, it will be appreciated by one of skill in the art that other devices external to the mobile device housing can be driven using an internal motor and protruding drive shaft arrangement, such as a vibrating tooth brush or personal massage device.

1. A mobile electronic device having a vibration alert system including control circuitry to control a vibration motor, the device comprising a personal cooling fan system controlled by the control circuitry, the personal cooling fan system including a rotary motor contained within a housing of the device, a drive shaft having a first portion engaged by the rotary motor and having a second portion protruding from the housing, and fan blades removably attached to the second portion of the drive shaft such that the rotary motor is operable to rotate the drive shaft thereby spinning the fan blades.

2. The device of claim 1, wherein the drive shaft is movable from a retracted position to an extended position such that in the extended position the second end is sufficiently far from the housing to allow the fan blades to be attached and to spin.

3. The device of claim 2, wherein moving the drive shaft between the retracted position and the extended position is performed manually.

4. The device of claim 2, wherein moving the drive shaft between the retracted position and the extended position is controlled by the control circuitry.

5. The device of claim 2, wherein a fan control signal is generated in response to moving the drive shaft to the extended position, the fan control signal used to prompt the control circuitry to control the rotary motor.

6. The device of claim 1, further comprising an eccentric weight engagable with an axial rod of the rotary motor to make the vibration motor.

7. The device of claim 6, wherein the eccentric weight is engaged with the axial rod when the drive shaft is in a retracted position, and the eccentric weight is disengaged from the axial rod when the drive shaft is in an extended position, such that in the extended position the second end is sufficiently far from the housing to allow the fan blades to be attached and to spin.

8. The device of claim 1, wherein the drive shaft includes multiple axially aligned members arranged in a nested fashion to telescopically extend from and retract into the housing.

9. The device of claim 1, wherein the drive shaft is removably engaged to the rotary motor.

10. The device of claim 1, wherein the fan blades are attached to a drive hub, the drive hub being removably attached to the drive shaft.

11. The device of claim 10, wherein the drive hub is removably attached to the drive shaft by a set screw.

12. The device of claim 10, wherein the fan blades are foldably attached to the drive hub.

13. The device of claim 10, wherein the fan blades are rigidly attached to the drive hub.

14. For use in a mobile electronic device having a vibration alert system including control circuitry to control a vibration motor, a personal cooling fan system controlled by the control circuitry and including a rotary motor contained within a housing of the device, a drive shaft having a first portion engaged by the rotary motor and having a second portion protruding from the housing, and fan blades removably attachable to the second portion of the drive shaft such that the rotary motor is operable to rotate the drive shaft thereby spinning the fan blades (160, 260, 360), a method comprising:
generating a fan control signal used to prompt the control circuitry to control the rotary motor;
attaching the fan blades to the second portion of the drive shaft; and
operating the fan using the control circuitry.

15. The method of claim 14, wherein the drive shaft is movable from a retracted position to an extended position, the fan blades being attached to the drive shaft in the extended position.

16. The method of claim 15, further comprising positioning the drive shaft in the extended position.

17. The method of claim 16, wherein the step of generating the fan control signal is performed in response to positioning the drive shaft in the extended position.

18. The method of claim 16, wherein positioning the drive shaft is performed manually by a user.

19. The method of claim 16, wherein positioning the drive shaft in the extended position is controlled automatically by the control circuitry in response to the fan control signal.

20. The method of claim 14, further comprising providing user prompts to control the fan speed.
